(19) United States
(12) Patent Application Publication
(10) Pub. No.: US 2026/0071329 A1
(43) Pub. Date: Mar. 12, 2026

(54) LIFTING APPARATUS AND CHEMICAL VAPOR DEPOSITION APPARATUS INCLUDING THE SAME

(71) Applicant: Samsung Display Co., LTD., Yongin-si (KR)

(72) Inventors: INKYO KIM, Yongin-si (KR); SEOK-JIN KO, Yongin-si (KR); YOUNGSEUNG KIM, Yongin-si (KR); HAEYOUNG YOO, Yongin-si (KR); DUCKHWAN YUN, Yongin-si (KR); DAEHYUN LEE, Yongin-si (KR); SIMYEONG LEE, Yongin-si (KR); HEUNGKYOON YIM, Yongin-si (KR); SINYOUNG HAN, Yongin-si (KR)

(21) Appl. No.: 19/198,855

(22) Filed: May 5, 2025

(30) Foreign Application Priority Data
Sep. 6, 2024 (KR) 10-2024-0121351

(51) Int. Cl. C23C 16/458

(52) U.S. Cl. CPC C23C 16/458

(57) ABSTRACT

A lifting apparatus includes a main plate, an auxiliary plate disposed on the main plate, a plurality of coupling units which connects the main plate to the auxiliary plate, a plurality of leg parts adjacent to both opposing sides of each of the main plate and the auxiliary plate and extending downward, a head part connected to the main plate and protruding upward, a plurality of connecting pillars connected to the main plate and extending downward, and a support ring connected to lower ends of the connecting pillars.

This application claims priority to Korean Patent Application No. 10-2024-0121351, filed on Sep. 6, 2024, and all the benefits accruing therefrom under 35 U.S. C. § 119, the content of which in its entirety is herein incorporated by reference.

### BACKGROUND

### (1) Field

Embodiments of the disclosure herein relate to a lifting apparatus and a chemical vapor deposition apparatus including the lifting apparatus.

### (2) Description of the Related Art

The methods of depositing a thin film on a substrate include physical vapor deposition (PVD) and chemical vapor deposition (CVD). The chemical vapor deposition method is defined as a method of depositing a thin film on a substrate through the chemical reaction of decomposed source gases after the source gases have been decomposed.

The plasma chemical vapor deposition method (e.g., plasma enhanced CVD (PECVD) method), among chemical vapor deposition methods, decomposes source gases using plasma. The plasma chemical vapor deposition apparatus includes a process chamber, a shower head disposed within the process chamber for injecting source gases, and a stage disposed below the shower head where the substrate is mounted.

Gas injection holes for spraying source gases are defined in the showerhead. The source gases are sprayed through the shower head, high-frequency power is applied to the shower head, and the stage is grounded, forming plasma according to the electric field. In accordance with this process, source gases are decomposed, and deposition materials generated from the chemical reactions of the decomposed source gases are deposited on the substrate to form a thin film.

### SUMMARY

A deposition material is deposited not only on a substrate but also in various locations within a chamber, and it may be deposited most heavily on a bottom surface of a shower head that discharges a source gas. If a deposition film deposited on the bottom surface of the shower head becomes thicker, the deposition film may be detached from the shower head, thereby forming contaminants. Therefore, a method for cleaning the shower head or for easily replacing the shower head is desired.

The disclosure provides a lifting apparatus with enhanced stiffness as thickness decreases and a chemical vapor deposition apparatus including the lifting apparatus.

An embodiment of the invention provides a lifting apparatus including: a main plate; an auxiliary plate disposed on the main plate; a plurality of coupling units which connects the main plate to the auxiliary plate; a plurality of leg parts adjacent to both opposing sides of each of the main plate and the auxiliary plate and extending downward; a head part connected to the main plate and protruding upward; a plurality of connecting pillars connected to the main plate and extending downward; and a support ring connected to lower ends of the connecting pillars.

In an embodiment of the invention, a chemical vapor deposition apparatus includes: a main plate extending longer in a first direction than a second direction which intersects the first direction; an auxiliary plate disposed on the main plate and connected to the main plate; a plurality of leg parts adjacent to both opposing sides of each of the main plate and the auxiliary plate and extending downward; a plurality of chamber connecting parts connected to lower ends of the leg parts; a head part connected to the main plate and protruding upward; a plurality of connecting pillars connected to the main plate and extending downward; a support ring connected to lower ends of the connecting pillars; an upper chamber connected to the support ring and the chamber connecting parts; and a lower chamber disposed below the upper chamber, wherein the upper chamber and the lower chamber are coupled to each other to define a process space in which a chemical vapor deposition process is performed, and a thickness of a central portion of the main plate is greater than a thickness of each of both opposing side portions of the main plate, which are opposite to each other in the first direction.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view illustrating a lifting apparatus of a chemical vapor deposition apparatus according to an embodiment of the invention;

FIG. 2 is a plan view of the lifting apparatus viewed from above in a state where components of the lifting apparatus shown in FIG. 1 are coupled to each other;

FIG. 3 is a cross-sectional view taken along line I-I′ of FIG. 2;

FIG. 4 is an enlarged view of a first area AA1 illustrated in FIG. 3;

FIG. 5 is an enlarged view of a second area AA2 illustrated in FIG. 3;

FIG. 6 is a cross-sectional view illustrating a process chamber of the chemical vapor deposition apparatus according to an embodiment of the invention;

FIG. 7 is a cross-sectional view of a pixel including a thin film provided using the chemical vapor deposition apparatus according to an embodiment of the invention;

FIG. 8 is a view of a crane connected to a head portion illustrated in FIG. 5;

FIGS. 9A to 9C are views illustrating a separation operation of an upper chamber using the lifting apparatus of the invention;

FIGS. 10A to 10C are views illustrating a deformation state of a comparative main plate according to an external force applied to a central portion of the comparative main plate;

FIGS. 11A and 11B are views illustrating a separation operation of an upper chamber using a comparative lifting apparatus;

FIGS. 12A to 12C are views illustrating a deformation state of the main plate due to an external force applied to the central portion of the main plate according to an embodiment of the invention;

FIG. 13 is a view illustrating a state in which stress is dispersed by coupling units and an auxiliary plate illustrated in FIG. 3;

FIG. 14 is a view illustrating a state in which the stress is dispersed in the enlarged view of FIG. 4;

FIG. 15 is a view illustrating a configuration of a lifting apparatus according to another embodiment of the invention; and

FIG. 16 is a view illustrating a deformation state of the main plate, auxiliary plate, and dummy auxiliary plate during the lifting operation of the upper chamber.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In this specification, it will also be understood that when one component or region, layer, portion is referred to as being “connected to”, or “coupled to” another component, it can be directly connected/coupled to the one component, or an intervening third component may also be present.

Like numbers refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the accompanying drawings.

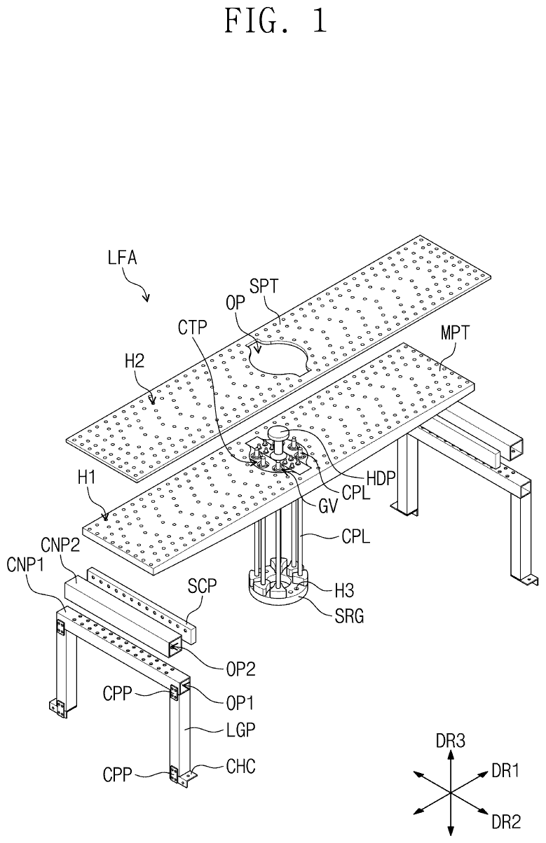

FIG. 1 is a perspective view illustrating a lifting apparatus of a chemical vapor deposition apparatus according to an embodiment of the invention;

Referring to FIG. 1, an embodiment of a lifting apparatus LFA may include a main plate MPT, an auxiliary plate SPT, a head part HDP, a plurality of connecting pillars CPL, a supporting ring SRG, a plurality of first connecting parts CNP1, a plurality of second connecting parts CNP2, a plurality of side connecting parts SCP, a plurality of leg parts LGP, a plurality of chamber connecting parts CHC, and a plurality of connecting plates CPP.

The main plate MPT may have a flat top surface defined by a first direction DR1 and a second direction DR2 crossing the first direction DR1. The main plate MPT may extend longer in the first direction DR1 than in the second direction DR2. When viewed on a plane, the main plate MPT may have a rectangular shape that has long sides extending in the first direction DR1 and short sides extending in the second direction DR2.

Hereinafter, a direction that is substantially perpendicular to the plane defined by the first direction DR1 and the second direction DR2 may be defined as a third direction DR3. The third direction DR3 may be a thickness direction of the main plate MPT. In addition, in this specification, “when viewed on the plane” may be defined as a state when viewed in the third direction DR3 or in a plan view.

The main plate MPT may include a central portion CTP. The central portion CTP may be defined as a portion of the main plate MPT adjacent to a center point of the main plate MPT based on the first direction DR1. The central portion CTP may have a predetermined shape. In an embodiment, for example, the central portion CTP may be defined to have a shape protruding in the second direction DR2 from a circular shape, as shown in FIG. 1. However, the shape of the central portion CTP is not limited thereto.

A plurality of first coupling holes H1 may be defined in the main plate MPT. The first coupling holes H1 may be defined or formed through the main plate MPT in the third direction DR3. The first coupling holes H1 may be defined between an edge of the central portion CTP and an edge of the main plate MPT. The first coupling holes H1 may be dispersed and arranged in an area between the edge of the central portion CTP and the edge of the main plate MPT. The first coupling holes H1 may be defined at various locations between the edge of the center part CTP and the edge of the main plate MPT.

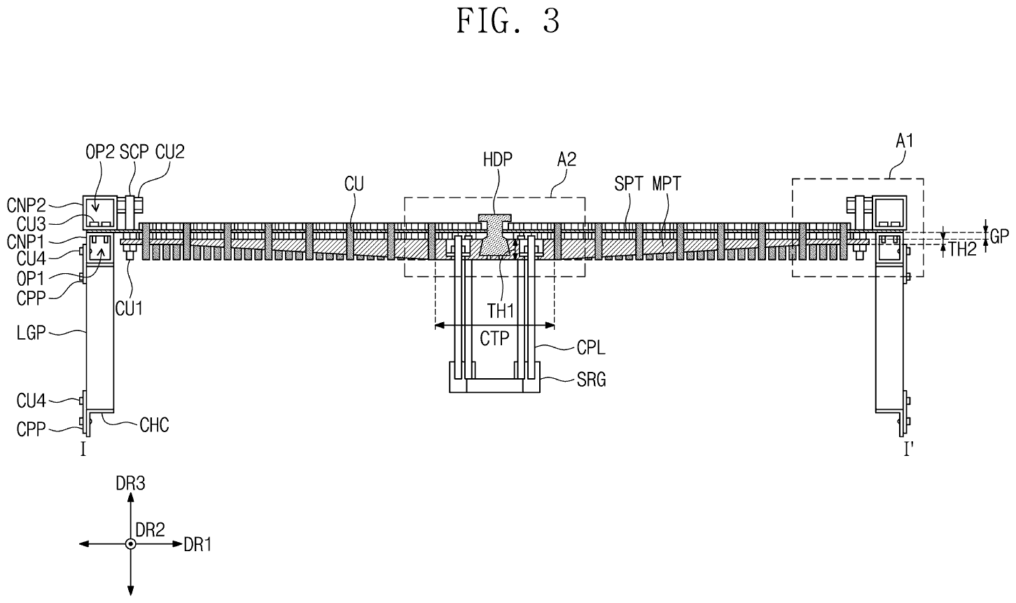

The auxiliary plate SPT may be disposed on the main plate MPT. When viewed on a plane, the main plate MPT may overlap the auxiliary plate SPT. The main plate MPT and the auxiliary plate SPT may be connected to each other by coupling units, and this configuration will be described in detail with reference to FIG. 3 below.

The auxiliary plate SPT may have a surface on a plane defined by the first direction DR1 and the third direction DR2. The auxiliary plate SPT may extend longer in the first direction DR1 than in the second direction DR2. When viewed on a plane, the auxiliary plate SPT may have a rectangular shape that has long sides extending in the first direction DR1 and short sides extending in the second direction DR2.

An opening OP may be defined in a central portion of the auxiliary plate SPT. The opening OP may be defined or formed through the auxiliary plate SPT in the third direction DR3. When viewed on a plane, the opening OP may overlap the central portion of the main plate MPT. The opening OP may be defined to have a shape corresponding to that of the central portion CTP.

A plurality of second coupling holes H2 may be defined in the auxiliary plate SPT. The second coupling holes H2 may be defined or formed through the auxiliary plate SPT in the third direction DR3. The second coupling holes H2 may be defined between an edge of the opening OP and the edge of the auxiliary plate SPT. The second coupling holes H2 may be dispersed and arranged in an area between the edge of the opening and the edge of the auxiliary plate SPT. The second coupling holes H2 may be defined at various locations between the edge of the opening OP and the edge of the auxiliary plate SPT.

The head part HDP may be connected to the main plate MPT and may protrude upward or in the third direction DR3. When viewed on a plane, the head part HDP may overlap the central portion of the main plate MPT. In an embodiment, for example, the head part HDP may overlap a center point of the central portion CTP and connected to the main plate MPT. The head part HDP may be exposed upward through the opening OP defined in the auxiliary plate SPT.

The connecting pillars CPL may be connected to the main plate MPT and may extend downward or in a direction opposite to the third direction DR3. Each of the connecting pillars CPL may extend in the third direction DR3. The third direction DR3 may be defined as a vertical direction that intersects perpendicularly with a top surface of the main plate MPT which is planar. The connecting pillar CPL may have a cylindrical shape extending in the third direction DR3.

When viewed on a plane, the head part CPL may overlap the central portion of the main plate MPT. When viewed on a plane, the connecting pillars CPL may be arranged adjacent to the head part HDP to surround the head part HDP. The connecting pillars CPL may be respectively disposed (or inserted) in a plurality of grooves GV defined in the central portion CTP of the main plate MPT and may extend downward.

The connecting pillars CPL may be exposed through the opening OP defined in the auxiliary plate SPT. In an embodiment, for example, upper ends of the connecting pillars CPL disposed in the grooves GV may be exposed upward through the opening OP.

When viewed on a plane or in a plan view, the support ring SRG may have a circular ring shape. The support ring SRG may be disposed below the central portion CTP. The support ring SRG may be disposed below the connecting pillars CPL and connected to lower ends of the connecting pillars CPL. A plurality of third coupling holes H3 may be defined in the support ring SRG.

The connecting pillars CPL may be arranged in a ring shape along the support ring SRG when viewed on a plane. The coupling holes H3 may be defined between a portion of connecting pillars CPL.

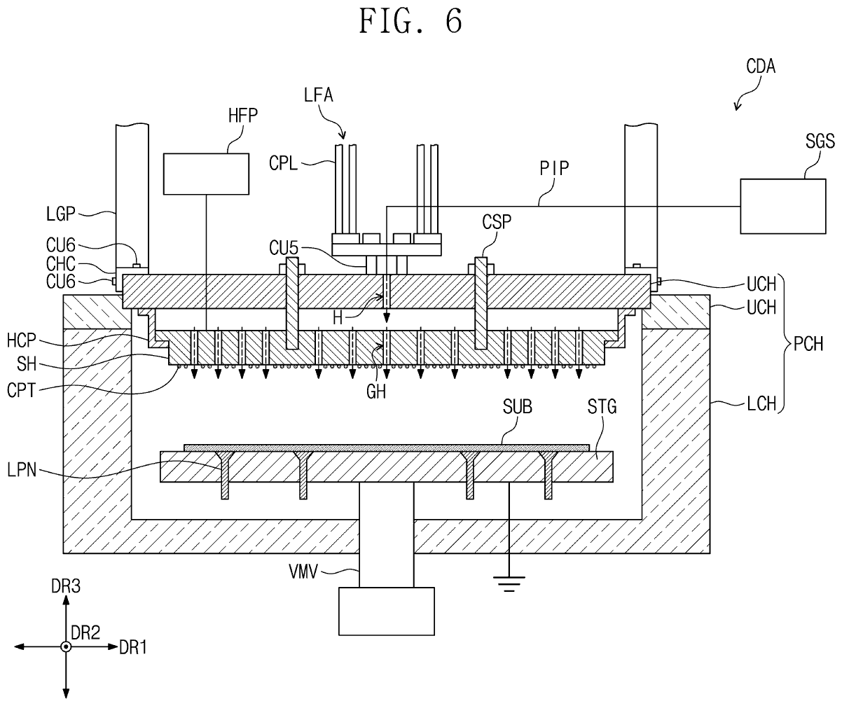

The support ring SRG may be connected to a process chamber, which will be described later in detail with reference to FIG. 6 below. Through the third coupling holes H3, the coupling units may connect the support ring SRG to the process chamber, and this configuration will be described in detail with reference to FIG. 6 below.

The first connecting parts CNP1 may extend in the second direction DR2 and spaced apart from the first direction DR1. The first connecting parts CNP1 may be adjacent to both opposing sides of the main plate MPT and the auxiliary plate SPT, which are opposite to each other in the first direction DR1.

Each of the first connecting parts CNP1 may have a rectangular pillar shape extending in the second direction DR2. The first connecting part CNP1 may have a pipe shape. In an embodiment, for example, a first opening OP1 that is opened in the second direction DR2 may be defined in each of the first connecting parts CNP1.

The second connecting parts CNP2 may extend in the second direction DR2 and spaced apart from the first direction DR1. The second connecting parts CNP2 may be adjacent to the both opposing sides of the main plate MPT and the auxiliary plate SPT, which are opposite to each other in the first direction DR1.

Each of the second connecting parts CNP2 may have a rectangular pillar shape extending in the second direction DR2. The second connecting part CNP2 may have a pipe shape. In an embodiment, for example, a second opening OP2 that is opened in the second direction DR2 may be defined in each of the second connecting parts CNP2.

The first and second openings OP1 and OP2 defined in the first and second connecting parts CNP1 and CNP2 may be defined as extended openings extending in the second direction DR2.

The second connecting part CNP2 may be disposed on the first connecting part CNP1. The second connecting parts CNP2 may be connected to the first connecting parts CNP1 by the coupling units. This configuration will be described in detail with reference to FIG. 3 below.

The side connecting parts SCP may extend in the second direction DR2 and spaced apart from the first direction DR1. The side connecting parts SCP may be adjacent to the both opposing sides of the main plate MPT and the auxiliary plate SPT, which are opposite to each other in the first direction DR1. The side connecting parts SCP may extend longer in the second direction DR2 than in the first and third directions DR1 and DR3. In addition, the side connecting parts SCP may extend longer in the third direction DR3 than in the first direction DR1.

The side connecting parts SCP may be disposed on inner side surfaces of the second connecting parts CNP2 facing each other in the first direction DR1, respectively. The side connecting parts SCP may be connected to inner side surfaces of the second connecting parts CNP2 by the coupling units, respectively. This configuration will be described in detail with reference to FIG. 3 below.

The leg parts LGP may be adjacent to the both opposing sides of the main plate MPT and the auxiliary plate SPT, which are opposite to each other in the first direction DR1. Each of the leg parts LGP may be disposed below the first connecting part CNP1 and extend downward. Each of the leg parts LGP may extend in the third direction DR3. Each of the leg parts LGP may be connected to the first connecting part CNP1. In an embodiment, for example, the leg parts LGP may be connected to both opposing sides of the first connecting parts CNP1, which are opposite to each other in the second direction DR2.

Each of the leg parts LGP may have a rectangular pillar shape extending in the second direction DR3. Although not shown, each of the leg parts LGP may have a hollow pipe shape that is opened in the third direction DR3.

The chamber connecting parts CHC may be disposed below the leg parts LGP, respectively. The chamber connecting parts CHC may be connected to lower ends of the leg parts LGP, respectively.

The connecting plates CPP may connect the first connecting part CNP1 to the leg part LGP, and also connect the leg part LGP to the chamber connecting part CHC, respectively. In an embodiment, for example, each of the connecting plates CPP is disposed on side surfaces, which are adjacent to each other, of the first connecting part CNP1 and leg part LGP and may be connected to the first connecting part CNP1 and the leg part LGP by coupling units not shown such as bolts. Thus, the first connecting part CNP1 and the leg part LGP may be connected to each other by the connecting plate CPP.

The connecting plates CPP may be disposed on the side surfaces, which are adjacent to each other, of the leg part LGP and chamber connecting part CHC, and may be connected to the leg part LGP and the chamber connecting part CHC by coupling units such as bolts not shown. Therefore, the leg part LGP and the chamber connecting part CHC may be connected to each other by the connecting plate CPP.

Although not shown in FIG. 1, holes for allowing the coupling units to be disposed may be defined in the first and second connecting parts CNP1 and CNP2, side connecting parts SCP, and chamber connecting parts CHC.

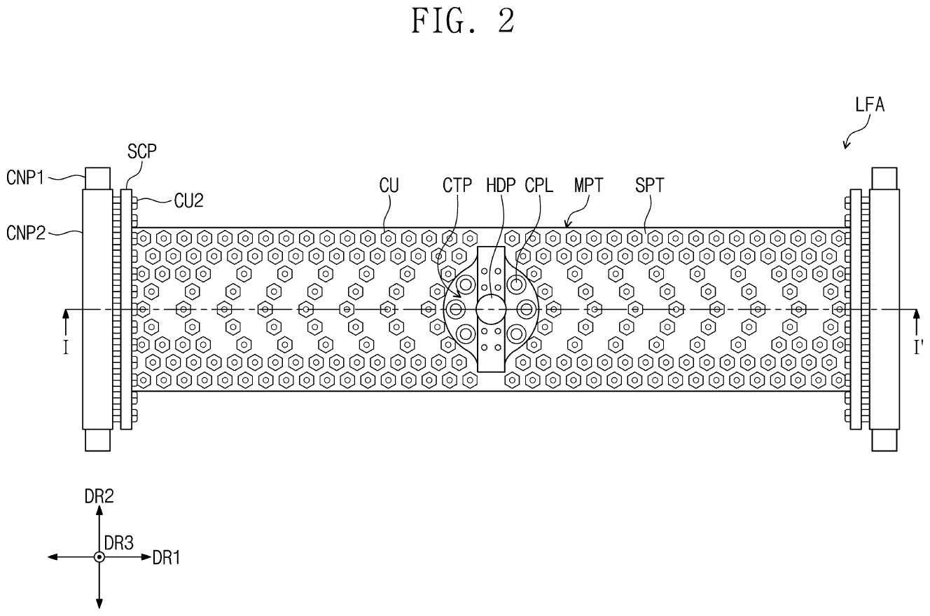

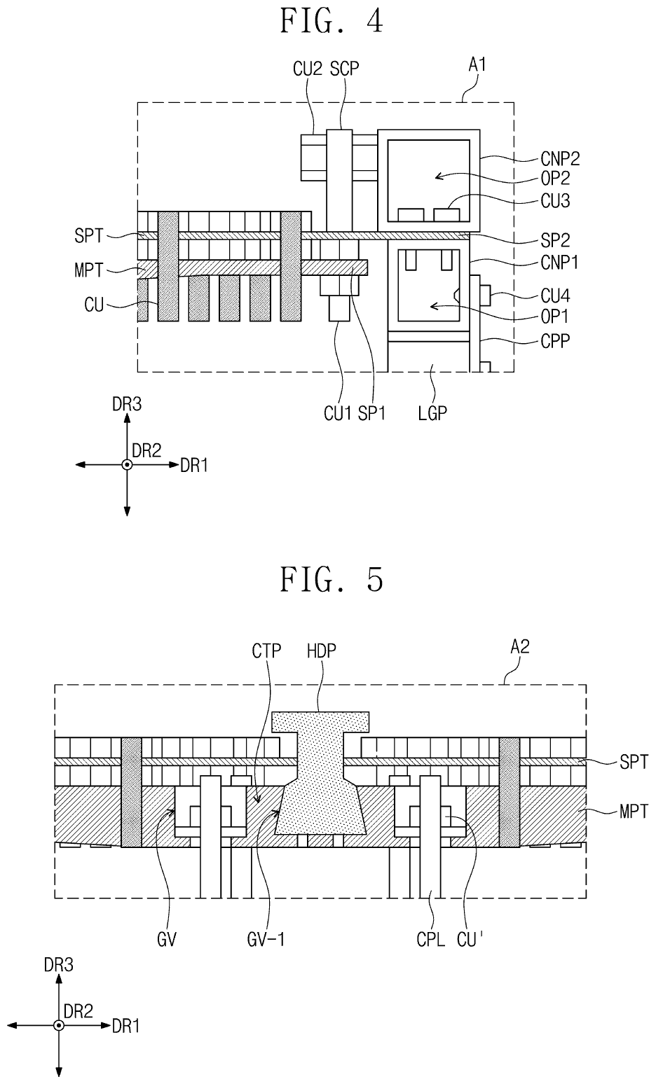

FIG. 2 is a plan view of the lifting apparatus viewed from above in a state where components of the lifting apparatus shown in FIG. 1 are coupled to each other. FIG. 3 is a cross-sectional view taken along line I-I′ of FIG. 2. FIG. 4 is an enlarged view of a first area AA1 illustrated in FIG. 3. FIG. 5 is an enlarged view of a second area AA2 illustrated in FIG. 3.

Referring to FIG. 2 and FIG. 3, in an embodiment, the main plate MPT and the auxiliary plate SPT may be arranged to be spaced apart by a predetermined interval GP in the third direction DR3. That is, the main plate MPT and the auxiliary plate SPT may not be in contact with each other. The main plate MPT may have a shorter length than the auxiliary plate SPT in the first direction DR1.

The lifting apparatus LFA may include a plurality of coupling units CU. The coupling units may extend in the third direction DR3. Each of the coupling units CU may connect the main plate MPT to the auxiliary plate SPT. The coupling unit CU may extend and penetrate through the main plate MPT and the auxiliary plate SPT from above the main plate MPT to below the auxiliary plate SPT.

The coupling unit CU may be inserted into the corresponding first and second holes H1 and H2, thereby allowing the main plate MPT and the auxiliary plate SPT to be connected to each other. The coupling unit CU may be implemented with various fastening structures such as bolts and nuts.

Also, in the specification, the expression of a “thickness” may be defined as a value measured in the third direction DR3.

The central portion CTP of the main plate MPT may have a predetermined thickness. The central portion CTP of the main plate MPT may have a first thickness TH1, and both opposing side surfaces of the main plate MPT, which are opposite to each other in the first direction DR1, may have a second thickness TH2. The first thickness TH1 may be greater than the second thickness TH2. The thickness between the side surfaces and the central portion CTP of the main plate MPT may gradually increase as being towards the central portion CTP from the side surfaces of the main plate MPT.

Since the coupling unit CU is inserted into the first hole H1, the coupling unit CU may be disposed between the central portion CTP and the edge of the main plate MPT. Also, the coupling units CU may be dispersed and disposed on the area between the central portion of the main plate and the edge of the main plate MPT.

Since the coupling unit CU is inserted into the second hole H2, the coupling unit CU may be disposed between the opening OP of the auxiliary plate SPT and the edge of the auxiliary plate SPT. In addition, the coupling units CU may be dispersed and disposed on the area between the opening and the edge of the auxiliary plate SPT.

Referring to FIGS. 2 to 4, an embodiment of the lifting apparatus LFA may include a plurality of first, second, third, and fourth coupling units CU1, CU2, CU3, CU4. The first, second, third, and fourth coupling units CU1, CU2, CU3, CU4 may be implemented with various fastening structures such as bolts and nuts.

The first coupling unit CU1 may extend in the third direction DR3 and may connect the main plate MPT and the auxiliary plate SPT to the side connecting part SCP. Portions of the main plate MPT, which are adjacent to both opposing sides of the main plate MPT, which are opposite to each other in the first direction DR1, may be defined as first side portions SP1. The first side portions SP1 and portions of the auxiliary plate SPT, which overlap the first side portions SP1, may be disposed below the side connecting parts SCP and be connected to lower portions on the side connecting parts SCP by the first coupling units CU1.

Although not shown in FIGS. 3 and 4, the first coupling units CU1 may be inserted into the corresponding first holes H1 and corresponding second holes H2 to be connected to the lower parts of the side connecting parts SCP.

The second coupling unit CU2 may extend in the first direction DR1 and may connect the side connecting part SCP to the second connecting part CNP2. Although not shown in FIGS. 3 and 4, the second coupling unit CU2 may be inserted into a hole defined in the side connecting part SCP and a hole defined in the second connecting part CNP2.

The third coupling unit CU3 may extend in the third direction DR3 and may connect the second connecting part CNP2 to the first connecting part CNP1. The third coupling unit CU3 may be disposed in the first and second openings OP1 and OP2. Although not shown in FIGS. 3 and 4, the third coupling unit CU3 may be inserted into holes defined in the first and second connecting parts CNP1 and CNP2.

The fourth coupling unit CU4 may extend in the first direction DR1 and may connect the connecting plate CPP to the first connecting part CNP1. Although not shown in FIGS. 3 and 4, the fourth coupling unit CU4 may be inserted into holes respectively defined in the first connecting part CNP1, the leg part LGP, and the chamber connecting part CHC.

Referring to FIGS. 2, 3, and 5, the head part HDP may be disposed in a groove GV-1 defined in the central portion CTP. A width of a lower portion of the head part HDP in the first direction DR1 or the second direction DR2 may gradually increase downward (i.e., as being toward a bottom surface of the central portion CTP), such that the head part HDP may be firmly fixed to the center part CTP. Additionally, the entire head part HDP may not be exposed to the central portion CTP, and only an upper portion of the head part HDP may be exposed to the central portion CTP.

In a case where the head part HDP is disposed on a top surface of the center part CTP and connected to the top surface of the center part CTP, a height of an upper end of the head part HDP may increase. However, in an embodiment of the invention, since the lower portion of the head part HDP is inserted into the groove GV-1, the height of the upper end of the head part HDP may be reduced.

The upper portion of the head part HDP may protrude above the auxiliary plate SPT through the opening OP of the auxiliary plate SPT. The connecting pillars CPL may be disposed below the auxiliary plate SPT. The lifting apparatus LFA may include the plurality of coupling units CU. The connecting pillars CPL may be connected to the central portion CTP through coupling units CU′ in the grooves GV.

FIG. 6 is a cross-sectional view illustrating a process chamber of the chemical vapor deposition apparatus according to an embodiment of the invention.

In an embodiment, for example, as shown in FIG. 6, the leg part LGP of the lifting apparatus LFA connected to a process chamber PCH, the chamber connecting parts CHC, connecting pillars CPL, the support ring SRG, and fifth coupling units CU5 are shown together with the process chamber PCH.

Referring to FIG. 6, a chemical vapor deposition apparatus CDA may include a lifting apparatus LFA, a process chamber PCH, a shower head SH, a connecting support part CSP, a head connecting part HCP, a stage STG, a plurality of lift pins LPN, a high-frequency power source unit HFP, a source gas supply unit SGS, a gas supply pipe PIP, and a vertical movement unit VMV. The shower head SH, the connecting support part CSP, the head connecting part HCP, the stage STG, and each of the lift pins LPN may be disposed in the process chamber PCH.

The process chamber PCH may be defined as a vacuum chamber. When a chemical vapor deposition process is carried out, the interior of the process chamber PCH may be maintained in a vacuum state. Although not shown, the chemical vapor deposition apparatus CDA may include a vacuum pump that maintains the process chamber PCH in a vacuum state, and is connected to the process chamber PCH.

The process chamber PCH may include an upper chamber UCH and a lower chamber LCH disposed below the upper chamber UCH. Both opposing sides of the upper chamber UCH may have a stepped shape. The upper chamber UCH and the lower chamber LCH may be connected to each other to define a process space for performing a chemical vapor deposition process. The shower head SH, the connecting support part CSP, the head connecting part HCP, the stage STG, and the lift pin LPN may be disposed in the process chamber PCH.

When the inside of the process chamber PCH is in a vacuum state due to the vacuum pump, the outside of the process chamber PCH may be at atmospheric pressure. In such cases, depending on an adsorption force due to the pressure difference, the upper chamber UCH and the lower chamber LCH may be coupled together. When the inside of the process chamber PCH is converted to atmospheric pressure, the upper chamber UCH and the lower chamber LCH may be easily separated from each other. However, the invention is not limited thereto, in an embodiment, the upper chamber UCH and the lower chamber LCH may be coupled to or separated from each other by coupling units such as screws.

The shower head SH may be connected to the upper chamber UCH within the process chamber PCH. In an embodiment, for example, the connecting support parts CSP connected to an upper end of the upper chamber UCH may extend in the third direction DR3 toward the inside of the process chamber PCH and be connected to the shower head SH. Each of the connection support parts CSP may effectively prevent the drooping of the shower head SH.

Both opposing sides of the shower head SH may be connected to the upper chamber UCH by the head connecting parts HCP. The head connecting parts HCP may be connected to a ceiling surface of the upper chamber UCH and the both opposing sides of the shower head SH within the process chamber PCH. Therefore, the shower head SH, the connecting support parts CSP, and the head connecting part HCP may be connected to the upper chamber UCH.

A plurality of gas injection holes GH may be defined in the shower head SH. The gas injection holes GH may be defined or formed through the shower head SH in the third direction DR3.

The stage STG may be disposed the shower head SH, and the vertical movement unit VMV may be disclosed below the stage STG. The vertical movement unit VMV may be connected to the stage STG to allow the stage STG to reciprocate in the third direction DR3.

A substrate SUB, which is an object to be processed, may be disposed on a top surface of the stage STG. The lift pin LPN may be disposed to penetrate through the stage STG. The substrate SUB may be disposed on the lift pins LPN. The stage STG, the substrate SUB, and the lift pins LPN may be disposed within the lower chamber LCH.

Although not shown, a gate valve may be defined in the lower chamber LCH, and the substrate SUB may be transferred into the process chamber PCH through the gate valve. The substrate SUB transferred into the process chamber PCH may be disposed on the lift pins LPN.

When the substrate SUB is transferred into the process chamber PCH, the top surface of the stage STG may be disposed lower than an upper end of each of the lift pins LPN. After the substrate SUB is disposed on the lift pins LPN, the stage STG may move upward by the vertical movement unit VMV to allow the substrate SUB to be seated on the top surface of the stage STG.

The source gas supply unit SGS may be connected to an upper end of the upper chamber UCH through the gas supply pipe PIP. In FIG. 6, the gas supply pipe PIP is shown by a line for convenience of illustration.

A hole H may be defined in the upper chamber UCH, and the gas supply pipe PIP may be connected to the hole H. The source gas supply unit SGS may provide source gases into the process chamber PCH via the gas supply pipe PIP and the hole H. The source gases may be supplied to the shower head SH and be injected into the process chamber PCH through the gas injection holes GH.

The high-frequency power supply unit HFP may be disposed on the upper chamber UCH and connected to the shower head SH disposed within the process chamber PCH. The high-frequency power supply unit HFP may supply high-frequency power to the shower head SH. The stage STG may be grounded.

When a high-frequency power supply is applied to the shower head SH and the stage STG is grounded, an electric field is provided, and plasma may be generated by the electric field. In accordance with this process, source gases are decomposed, and deposition materials generated from the chemical reactions of the decomposed source gases are deposited on the substrate SUB to provide a thin film. In an embodiment, for example, the thin film may be a silicon oxide (SiO₂) film.

The deposition material is deposited not only on the substrate but also in various locations within the process chamber PCH, and particularly, the deposition material may be deposited most heavily on a bottom surface of the shower head that discharges the source gases. When the deposition film deposited on the bottom surface of the shower head SH becomes thicker, the deposition film may be detached from the shower head SH, thereby forming contaminants CPT.

When the deposited material on the lower surface of the shower head SH reaches a predetermined thickness, the shower head SH may be replaced. In an embodiment, for example, the upper chamber UCH connected to the shower head SH may be separated from the lower chamber LCH to remove the contaminated shower head SH, and then a new upper chamber UCH, to which a new shower head SH is connected, may be coupled to the lower chamber LCH.

The lifting apparatus LFA may be used to separate the upper chamber UCH from the lower chamber LCH. The lifting apparatus LFA may be connected to the upper chamber UCH.

The support ring SRG may be connected to the upper chamber UCH through the fifth coupling units CU5. In an embodiment, for example, the fifth coupling units CU5 may be inserted into the third holes H3 illustrated in FIG. 1, and the fifth coupling units CU5, which have a structure similar to that of screws, may be connected to the upper chamber UCH. Thus, the support ring SRG may be connected to the upper chamber UCH by the fifth connecting units CU5. The connecting pillars CPL may be connected to the upper chamber UCH by the support ring SRG.

The chamber connecting parts CHC may be connected to both opposing sides of the upper chamber UCH which is provided in a stepped manner. In an embodiment, for example, chamber connecting parts CHC may be connected to the both opposing sides of the upper chamber UCH, which are provided in a stepped manner, through the sixth coupling units CU6. The leg parts LGP may be connected to the upper chamber UCH through the chamber connecting parts CHC.

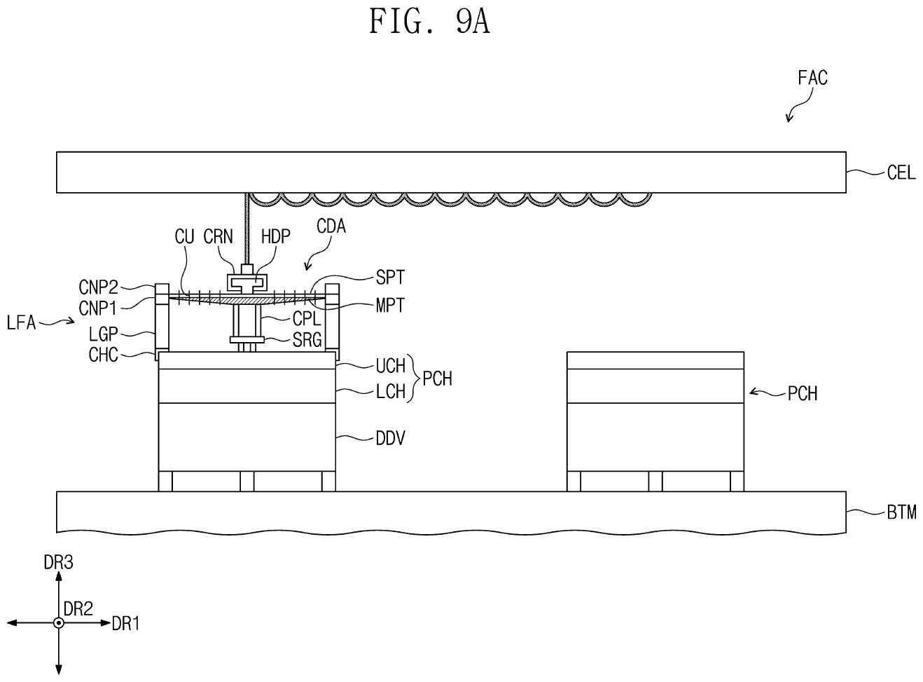

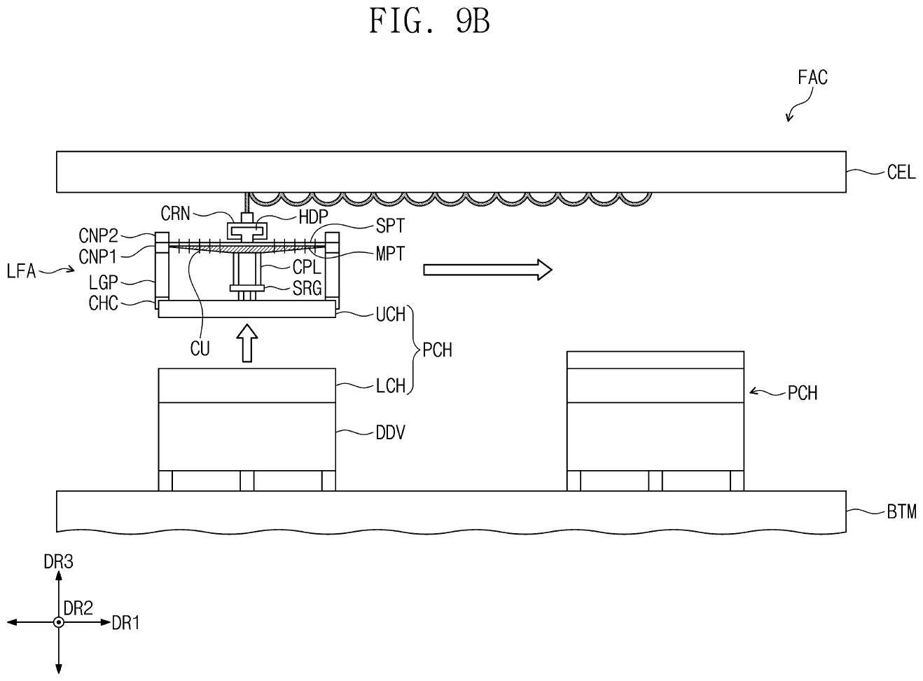

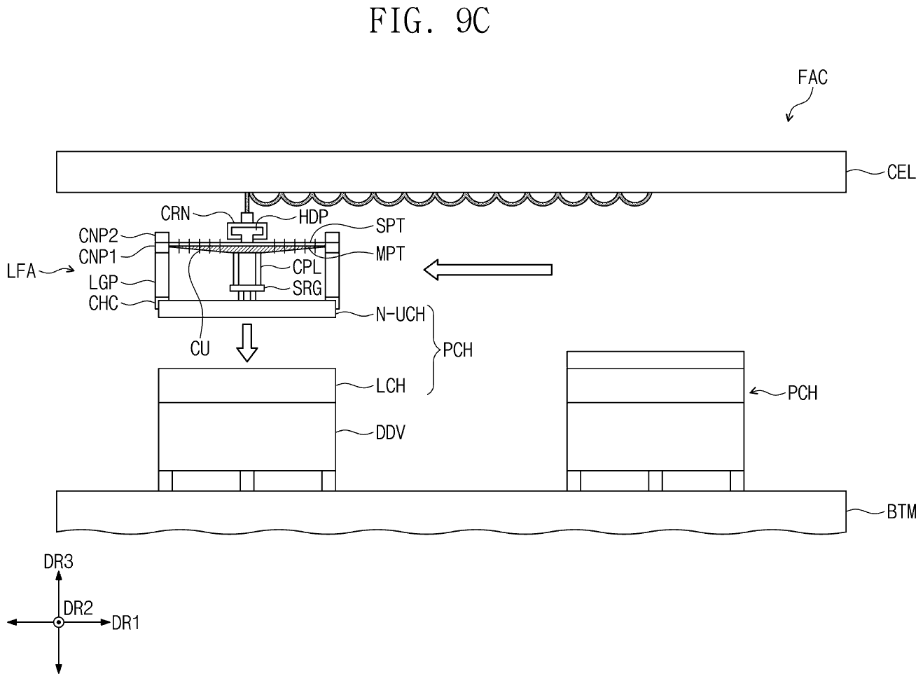

The lifting apparatus LFA may be connected to the process chamber PCH by connecting the support ring SRG and the chamber connecting parts CHC to the upper chamber UCH. The lifting apparatus LFA may move upward by the crane, and the upper chamber UCH connected to the lifting apparatus LFA may be separated from the lower chamber LCH. Therefore, the contaminated shower head SH connected to the upper chamber UCH may be removed. This operation will be described in detail below, with reference to FIGS. 9A and 9B.

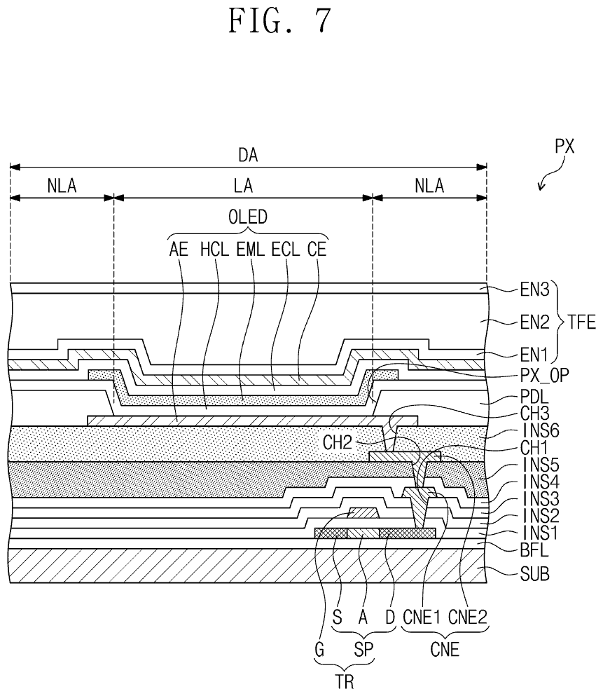

FIG. 7 is a cross-sectional view of a pixel including a thin film provided using the chemical vapor deposition apparatus according to an embodiment of the invention.

Among the layers shown in FIG. 7, a silicon oxide layer may be formed by the chemical vapor deposition apparatus CDA according to an embodiment of the invention.

Referring to FIG. 7, in an embodiment, a pixel PX may include a transistor TR and an organic light-emitting element OLED. The light emitting element OLED may include a first electrode AE or anode, a second electrode CE or cathode, a hole control layer HCL, an electron control layer ECL, and an emission layer EML.

The transistor TR and the light emitting element OLED may be disposed on the substrate SUB. Although one transistor TR is illustrated in FIG. 7 as an example, substantially, the pixel PX may include a plurality of transistors and at least one capacitor for driving the light emitting element OLED.

A display area DA may include a light emitting area LA corresponding to each of the pixels PX and a non-light emitting area NLA surrounding the light emitting area LA. The light emitting element OLED may be disposed in the emission area LA.

A buffer layer BFL may be disposed on the substrate SUB, and the buffer layer BFL may be an inorganic layer. A semiconductor pattern is disposed on the buffer layer BFL. The semiconductor pattern SP may include polysilicon, amorphous silicon, or metal oxides.

The semiconductor pattern may be doped with an N-type dopant or a P-type dopant. The semiconductor pattern may include a highly-doped region and a lightly-doped region. The highly-doped region may have conductivity greater than that of the low-doped region and may substantially serve as source and drain electrodes of the transistor TR. The low-doped region may effectively correspond to an active or channel of the transistor.

A source S, an active A, and a drain D of the transistor TR may be provided from (or defined by portions of) the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR and the light emitting element OLED. The first connection electrode CNE1 may be disposed on the third insulating layer INS3 and connected to the drain D through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second electrode CNE2 may be connected to the first connection electrode CNE1 through a second contact hole CH2 defined in the fourth and fifth insulating layers INS4 and INS5. A sixth insulating layer INS6 may be disposed on the second connection electrode CNE2.

The layers from the buffer layer BFL to the sixth insulating layer INS6 may be defined as the circuit element layer DP-CL. The buffer layer BFL and the first to fourth insulating layers INS1 to INS4 may each include inorganic layers. The fifth and sixth insulating layers INS5 and INS6 may each include organic layers.

In an embodiment, for example, the buffer layer BFL and the first insulating layer INS1 may each include a silicon oxide layer, and the second insulating layer INS2 may include a silicon nitride layer. The third insulating layer INS3 may include a plurality of inorganic insulating layers including or composed of different materials and laminated on each other. I an embodiment, for example, the third insulating layer INS3 may include a silicon nitride layer and a silicon oxide layer. The fourth insulating layer INS4 may include a silicon oxide layer.

The first electrode AE may be disposed on the sixth insulating layer INS6. The first electrode AE may be connected to the second connection electrode CNE2 through the third contact hole CH3 defined in the sixth insulating layer INS6. A pixel defining layer PDL with an opening PX_OP defined therein to expose a predetermined portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emission layer EML may be disposed on the hole control layer HCL. The emission layer EML may be disposed on an area corresponding to the opening OP. The emission layer EML may include organic and/or inorganic materials. The emission layer EML may emit one of red light, green light, and blue light.

The electron control layer ECL may be disposed on the emission layer EML and the hole control layer HCL. The electron control layer ECL may include an electron transport layer and an electron injection layer. The hole control layer HCL and the electron control layer ECL may be commonly disposed on the light emitting region LA and the non-light emitting region NLA.

The second electrode CE may be disposed on the electronic control layer ECL. The second electrode CE may be commonly disposed on the pixels PX. The layer on which the light emitting element OLED is disposed may be defined as the display element layer DP-OLED.

The thin film encapsulation layer TFE may be disposed on the second electrode CE to cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

Each of the first and third encapsulation layers EN1 and EN3 may include an inorganic insulating layer to protect the pixel PX from moisture/oxygen. The second encapsulation layer EN2 may include an organic insulating layer to protect the pixel PX from foreign substances such as dust particles.

A first voltage may be applied to the first electrode AE through the transistor TR, and a second voltage having a lower level than the first voltage may be applied to the second electrode CE. A hole and an electron injected into the light emitting layer EML are coupled to each other to form an exciton, and while the exciton is transited to a ground state, the light emitting element OLED may emit light.

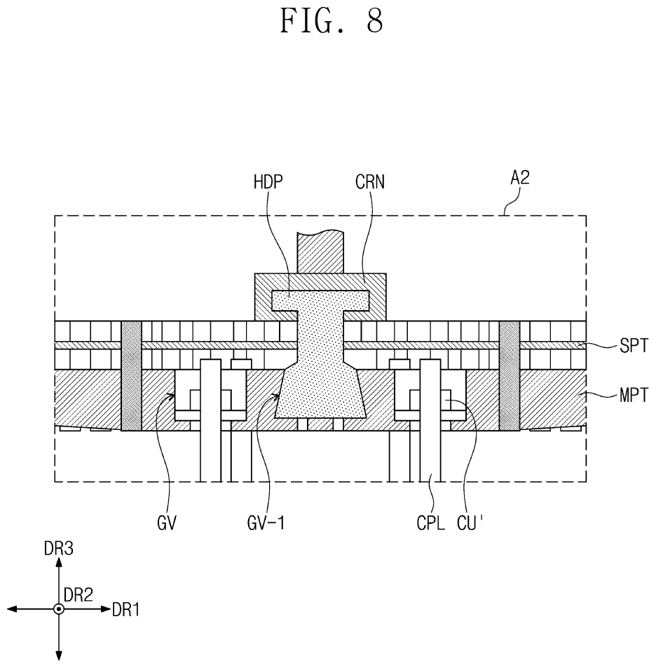

FIG. 8 is a view of a crane connected to a head portion illustrated in FIG. 5.

Referring to FIGS. 6 and 8, in an embodiment, the lifting apparatus LFA connected to the process chamber PCH may be connected to a crane CRN. The crane CRN may be connected to the head part HDP of the lifting apparatus LFA.

The crane CRN may move up and down (for example, in the third direction DR3). As the crane CRN moves upward, the lifting apparatus LFA may also move upward. The crane CRN illustrated in FIG. 8 may be a hook of the crane CRN. Since the crane CRN is connected to the head part HDP, the crane CRN may be connected to a center of the main plate MPT. Therefore, an external force may be applied by the crane CRN to the center of the main panel MPT.

FIGS. 9A to 9C are views illustrating a separation operation of an upper chamber using the lifting apparatus of the invention.

For the convenience of illustration and description, in FIGS. 9A to 9C, the lifting apparatus LFA and the process chamber PCH are depicted in a simplified manner compared to the structures described earlier.

Referring to FIG. 9A, in a factory FAC in which the chemical vapor deposition process is performed, a plurality of process chambers PCH and a plurality of driving devices DDV disposed below the process chambers PCH may be disposed. The driving devices DDV may be configured with various components that control the operations performed in the process chambers PCH, such as the above-described vacuum pump and vertical movement unit VMV.

The crane CRN may be connected to a ceiling CEL of the factory FAC. The driving devices DDV may be disposed on a bottom BTM of the factory FAC.

The crane CRN may be connected to the head part HDP of the lifting apparatus LFA. The lifting apparatus LFA may be connected to the upper chamber UCH of a process chamber PCH in which a contaminated shower head SH is disposed inside.

Referring to FIG. 9B, the crane CRN may lift the lifting apparatus LFA upward, and the lifting apparatus LFA may lift the upper chamber UCH. The upper chamber UCH may be separated from the lower chamber LCH and moved upward by the lifting apparatus LFA. The separated upper chamber UCH may be moved in the first direction DR1 to be replaced. The upper chamber UCH may move higher than the other process chamber PCH and be moved in the first direction DR1.

Referring to FIG. 9C, a new upper chamber N-UCH may be connected to the lifting apparatus LFA. A new shower head may be disposed inside the new upper chamber N-UCH. The crane CRN may move the lifting apparatus LFA and the new upper chamber N-UCH onto the lower chamber LCH. Afterward, the new upper chamber N-UCH may be moved downward toward the lower chamber LCH by the crane CRN and lifting apparatus LFA. Therefore, the new upper chamber N-UCH may be coupled to the lower chamber LCH.

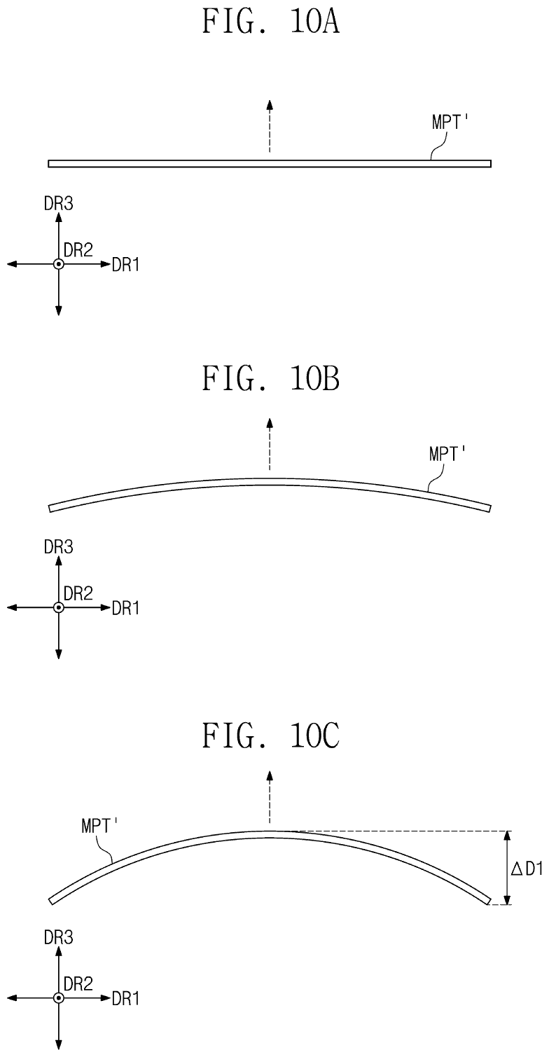

FIGS. 10A to 10C are views illustrating a deformation state of a comparative main plate according to an external force applied to a central portion of the comparative main plate.

Referring to FIGS. 10A, 10B, and 10C, the comparative main plate MPT′ may have a predetermined thickness. When a lifting apparatus that includes a comparative main plate MPT′ instead of the main plate MPT according to an embodiment of the invention is used, referring to the separation operation of the above-described upper chamber UCH, an external force may be applied to a center of the comparative main plate MPT′ by the crane CRN.

As the center of the comparative main plate MPT′ is lifted upward, the comparative main plate MPT′ may deform. As the center of the comparative main plate MPT′ is positioned above both opposing sides of the comparative main plate MPT′ in a deformed state, the comparative main plate MPT′ may have a curved shape upward.

Accordingly, stress may occur on the comparative main plate MPT′ depending on the deformation of the comparative main plate MPT′. A deformation amount of the comparative main plate MPT′ is defined as a distance between the lowest point and the highest point of the deformed comparative main plate MPT′, and is hereinafter referred to as a first deformation amount ΔD1.

Stress may be defined as internal resistance, deformation force, or internal force that occurs within a material when an external force is applied to the material. Stress and strain may be proportional. In other words, the greater the strain, the greater the stress may be.

The comparative main plate MPT′ having a relatively thin thickness may be deformed to bend significantly upward according to the external force applied to the center of the comparative main plate MPT′. When the deformation of the comparative main plate MPT′ increases, the external force on the comparative main plate MPT′ will increase, which may raise the possibility of damage to the comparative main plate MPT′. Therefore, when using the comparative main plate MPT′ shown in FIGS. 10A to 10C to lift the upper chamber UCH, the comparative main plate MPT′ may be damaged.

The thicker the object, the smaller the deformation of the object, and the stress may decrease. To prevent the above-described damage, a lifting plate having a relatively great thickness may be used. However, in such cases, the following issues may arise.

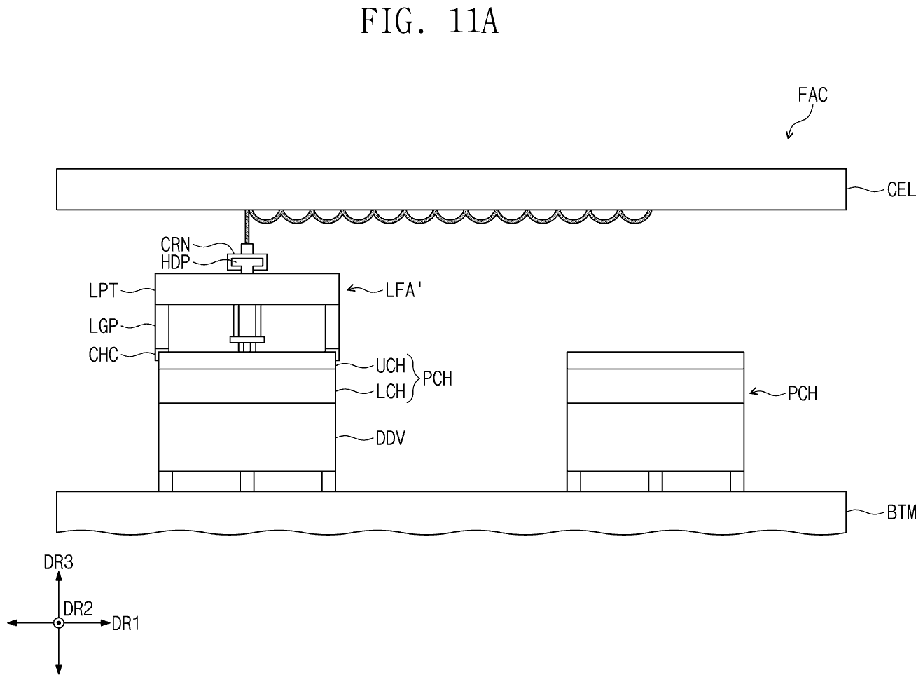

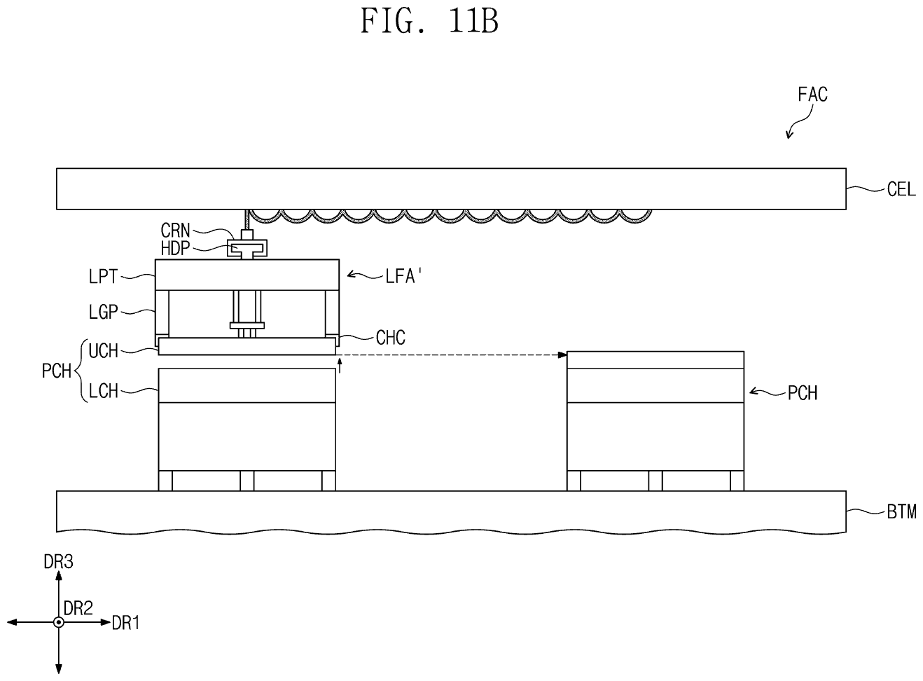

FIGS. 11A and 11B are views illustrating a separation operation of the upper chamber using the comparative lifting apparatus.

Particularly, FIGS. 11A and 11B illustrate side views corresponding to FIGS. 9A to 9B.

Hereinafter, the configurations shown in FIGS. 11A and 11B will be described mainly in terms of the configurations different from those shown in FIGS. 9A and 9B.

Referring to FIGS. 11A and 11B, a comparative lifting apparatus LFA′ may include a lifting plate LPT disposed on leg parts LGP. The lifting plate LPT may have a thickness greater than the above-described comparative main plate MPT′ and the main plate MPT.

The head part HDP may be disposed on the lifting plate LPT and may be connected to the lifting plate LPT. The crane CRN may lift the head part HDP, allowing the lifting plate LPT to move upward. However, as the thickness of the lifting plate LPT increases, the space for upward movement may be limited. For example, when the comparative lifting apparatus LFA′ shown in FIG. 11A is used instead of an embodiment of the lifting apparatus LFA shown in FIG. 9A, the lifting height may be relatively low.

Therefore, when the crane CRN and the comparable lifting apparatus LFA′ transfer the upper chamber UCH separated from the lower chamber LCH in the first direction DR1, the upper chamber UCH, which is being transferred, may collide with another process chamber PCH.

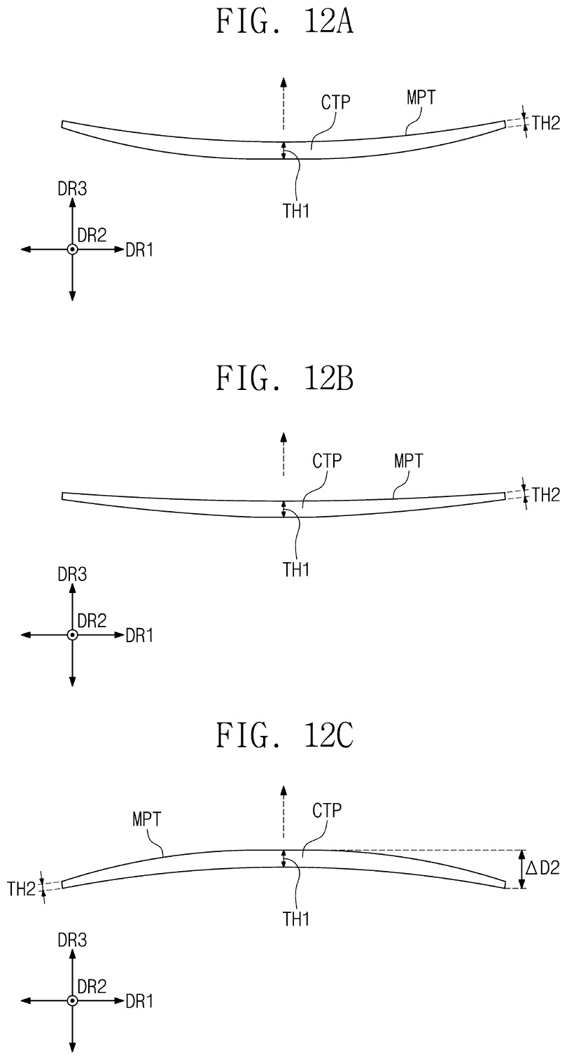

FIGS. 12A to 12C are views illustrating a deformation state of the main plate due to an external force applied to the central portion of the main plate according to an embodiment of the invention.

Referring to FIG. 12A, as described above, the thickness of the central portion CTP of the main plate MPT may be greater than the thickness of both opposing side surfaces of the main plate MPT. Therefore, a weight of the central portion CTP of the main plate MPT may be greater than that of other portions of the main plate MPT.

Since the center portion CTP is heavier, the center portion CTP of the main plate MPT may sag downward due to the influence of gravity. In FIGS. 1 and 3, for the convenience of illustration, the main plate MPT is depicted in a horizontal state, however, substantially, the main plate MPT may have a shape that is bent downward due to the weight of its central portion CTP. In other words, the main plate MPT may be linearly deformed and disposed on the process chamber PCH. Substantially, the linearly deformed main plate MPT may be connected to the upper chamber UCH.

Referring to FIGS. 12B and 12C, the external force may be applied to the center of the main plate MPT by the crane CRN. As the center of the comparative main plate MPT′ is lifted upward, the comparative main plate MPT′ may deform.

In an embodiment, the main plate MPT is linearly deformed to bend downward, when the center of the main plate MPT is lifted upward, such that the deformation amount of the main plate MPT bending upward may be reduced. In such an embodiment, since the deformation amount of the main plate MPT bending upwards is offset by the pre-deformed deformation amount of the main plate MPT, the deformation amount of the main plate MPT bending upwards may be reduced.

Referring to FIG. 12C, a deformation amount of the main plate MPT is defined as a distance between the lowest point and the highest point of the deformed main plate MPT, and is hereinafter referred to as a second deformation amount ΔD2.

Referring to FIGS. 10C and 12C, in a final deformed state, the second deformation amount ΔD2 of the main plate MPT may be less than the first deformation amount ΔD1 of the comparative main plate MPT′.

As described above, the greater the deformation of an object, the greater the stress therein, and the greater the stress on an object, the higher the likelihood of causing damage to the object. Since the second deformation amount ΔD2 of the main plate MPT is less than the first deformation amount ΔD1 of the comparative main plate MPT′, the damage to the main plate MPT may be substantially reduced or effectively prevented during the lifting operation of the upper chamber UCH using the main plate MPT.

In an embodiment of the invention, since the lifting apparatus LFA including the main plate MPT with the thickness less than that of the lifting plate LPT shown in FIGS. 11A and 11B is used, the upper chamber UCH may be transferred further higher, as shown in FIGS. 9A and 9B. In addition, in an embodiment of the invention, since the deformation of the main plate MPT due to the external force applied to the center of the main plate MPT is reduced, damage to the main plate MPT may be reduced. As a result, the damage to the lifting apparatus LFA may be reduced.

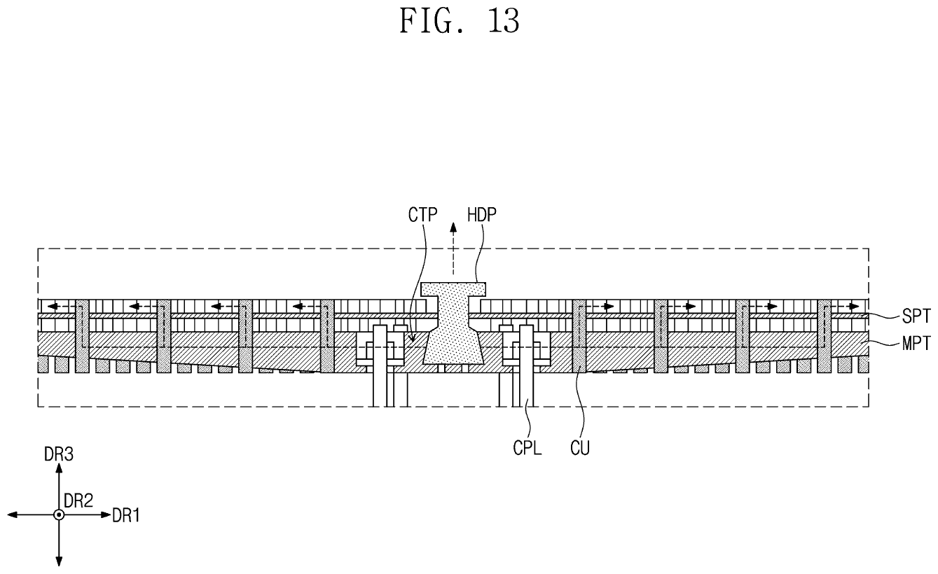

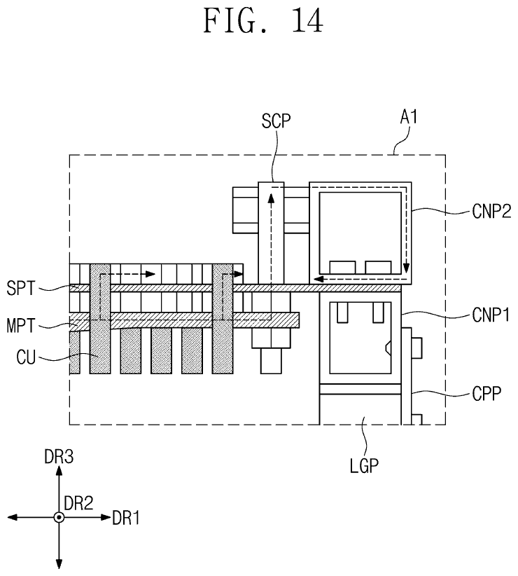

FIG. 13 is a view illustrating a state in which the stress is dispersed by coupling units and the auxiliary plate illustrated in FIG. 3. FIG. 14 is a view illustrating a state in which stress is dispersed in the enlarged view of FIG. 4.

For example, FIG. 13 illustrates an enlarged view of a portion of the main plate MPT and a portion of the auxiliary plate SPT adjacent to a central portion of the lifting apparatus LFA.

Referring to FIGS. 13 and 14, as described above, when the external force is applied to the central portion of the main plate MPT by the crane CRN, the main plate MPT may bend upward and stress may occur on the central portion of the main plate MPT.

The stress generated in the central portion of the main plate MPT may be dispersed along the coupling units CU and the auxiliary plate SPT as shown by dotted arrows in FIG. 13. Additionally, the stress generated in the main plate MPT may be dispersed along the coupling units CU, the auxiliary plate SPT, the side connection part SCP, and the pipe-shaped second connection part CNP2, as shown by dotted arrows in FIG. 14. Therefore, stress is not concentrated in one area but is dispersed, which may further reduce damage to the main plate MPT.

As a result, in an embodiment of the invention, the deformation of the main plate MPT due to the external force applied to the central portion of the main plate MPT may be reduced, and the stress of the main plate MPT may be dispersed through the coupling units CU and the auxiliary plate SPT. According to this structure, the stiffness of the lifting apparatus LFA is enhanced, which may reduce damage to the lifting apparatus LFA.

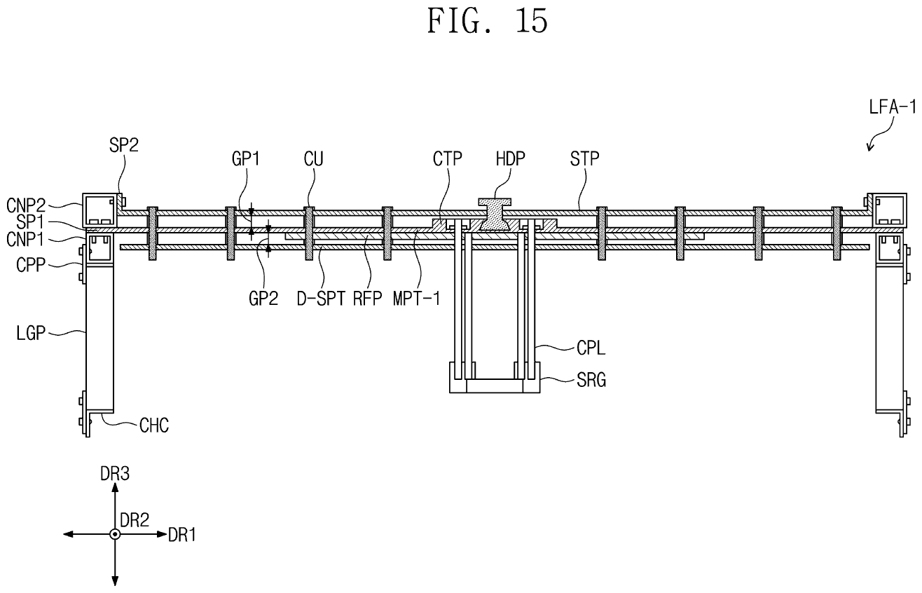

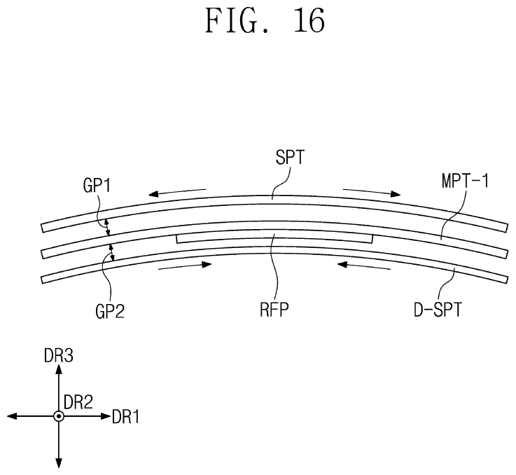

FIG. 15 is a view illustrating a configuration of a lifting apparatus according to another embodiment of the invention. FIG. 16 is a view illustrating a deformation state of a main plate, an auxiliary plate, and a dummy auxiliary plate during a lifting operation of an upper chamber.

For example, FIG. 15 illustrates a cross-section corresponding to FIG. 3, and the configurations depicted in FIG. 15 will be described primarily focusing on those different from the configurations shown in FIG. 3. Additionally, for the convenience of illustration, a smaller number of coupling units CU than those shown in FIG. 3 are depicted in FIG. 15. For example, in FIG. 16, a main plate MPT-1, a reinforcement plate RFP, an auxiliary plate SPT, and a dummy auxiliary plate D-SPT are briefly illustrated, and other configurations are omitted.

Referring to FIG. 15, an embodiment of a lifting apparatus LFA-1 may further include the dummy auxiliary plate D-SPT disposed below the main plate MPT-1 and the reinforcing plate RFP disposed below the main plate MPT-1. The dummy auxiliary plate D-SPT may be connected to the main plate MPT-1 by coupling units CU.

The main plate MPT-1 may be disposed between the auxiliary plate SPT and the dummy auxiliary plate D-SPT. The main plate MPT-1 may be spaced apart from the auxiliary plate SPT and the dummy auxiliary plate D-SPT in the third direction DR3. The main plate MPT-1 may be disposed at a center of an area between the auxiliary plate SPT and the dummy auxiliary plate D-SPT. In an embodiment, for example, a first gap GP1 between the main plate MPT-1 and the auxiliary plate SPT in the third direction DR3 may be the same as a second gap GP2 between the main plate MPT-1 and the dummy auxiliary plate D-SPT in the third direction DR3.

First side portions SP1 of the main plate MPT-1 may be disposed between first connecting parts CNP1 and second connecting parts CNP2 and be connected to the first connecting parts CNP1 and the second connecting parts CNP2. Second side portions SP2 of the auxiliary plate SPT may be bent upward to be connected to inner surfaces of the first connecting parts CNP1.

Both opposing sides of the reinforcement plate RFP, which are opposite to each other in the first direction DR1, may respectively be spaced apart from both opposing sides of the main plate MPT-1, which are opposite to each other in the first direction DR1, and thus may be disposed below the main plate MPT-1. The reinforcement plate RFP may overlap a central portion CTP of the main plate MPT-1. An edge of the reinforcement plate RFP may be adjacent to the central portion CTP rather than a corresponding side of the main plate MPT-1. That is, the edge of the reinforcement plate RFP may be closer to the central portion CTP than to the corresponding side of the main plate MPT-1.

The reinforcement plate RFP may be in contact with a bottom surface of the main plate MPT-1 and also be connected to the main plate MPT-1. The reinforcement plate RFP may be connected to the main plate MPT-1 by the coupling units CU. Depending on a weight of the reinforcement plate RFP, as shown in FIG. 12A, the main plate MPT-1 may be linearly deformed to sag downward.

Referring to FIG. 16, a head part HDP may be lifted upward by the above-described crane CRN. In this case, the main plate MPT-1, the auxiliary plate SPT, and the dummy auxiliary plate D-SPT may be deformed to bend upward.

As indicated by the arrows in the drawing, tensile stress may occur in the auxiliary plate SPT, and compressive stress may occur in the dummy auxiliary plate D-SPT. However, in the main plate MPT-1 disposed at the center of the area between the auxiliary plate SPT and the dummy auxiliary plate D-SPT, tensile and compressive stresses may be offset. In such cases, internal stress of the main plate MPT-1 may be minimized. Additionally, the stress on the main plate MPT-1 may be dispersed through the coupling units CU, the auxiliary plate SPT, and the dummy auxiliary plate D-SPT. Therefore, the damage to the main plate MPT-1 may be reduced.

The lifting apparatus according to an embodiment of the invention may include the main plate with the thick central portion and thinner sides, the auxiliary plate disposed on the main plate, and coupling units connecting the main plate and the auxiliary plate to each other.

In such an embodiment, when the upper chamber connected to the main plate is lifted upward, the deformation of the main plate due to the external force applied to the central portion of the main plate is reduced due to the structure of the main plate, and the stress of the main plate may be dispersed through the coupling units and the auxiliary plate. Therefore, the stiffness of the lifting apparatus is enhanced, which may reduce deterioration of the lifting apparatus.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A lifting apparatus comprising:
a main plate;
an auxiliary plate disposed on the main plate;
a plurality of coupling units which connects the main plate to the auxiliary plate;
a plurality of leg parts adjacent to both opposing sides of each of the main plate and the auxiliary plate and extending downward;
a head part connected to the main plate and protruding upward;
a plurality of connecting pillars connected to the main plate and extending downward; and
a support ring connected to lower ends of the connecting pillars.

2. The lifting apparatus of claim 1, wherein
the main plate and the auxiliary plate extend longer in a first direction than a second direction, which intersects the first direction, and
when viewed on a plane defined by the first and second directions, the head part and the connecting pillars are connected to a central portion of the main plate.

3. The lifting apparatus of claim 2, wherein the central portion has a thickness greater than a thickness of each of both opposing side portions of the main plate, which are opposite to each other in the first direction.

4. The lifting apparatus of claim 3, wherein a thickness of the main plate gradually increases as being toward the central portion from the opposing side portions thereof.

5. The lifting apparatus of claim 3, wherein the coupling units extend in a vertical direction perpendicular to the plane.

6. The lifting apparatus of claim 2, wherein, when viewed on the plane, the connecting pillars are adjacent to the head part and surround the head part.

7. The lifting apparatus of claim 2, wherein the coupling units are disposed between the central portion and an edge of the main plate.

8. The lifting apparatus of claim 7, wherein the coupling units are dispersed in an area between the central portion and the edge of the main plate.

9. The lifting apparatus of claim 2, wherein a lower portion of the head part is disposed in a groove defined in the central portion.

10. The lifting apparatus of claim 9, wherein a width of the lower portion of the head part in the first direction gradually increases downward.

11. The lifting apparatus of claim 2, wherein an opening exposing the head part and the connecting pillars is defined in the auxiliary plate.

12. The lifting apparatus of claim 11, wherein the coupling units are dispersed in an area between an edge of the opening and an edge of the auxiliary plate.

13. The lifting apparatus of claim 11, wherein
an upper portion of the head part protrudes higher than the auxiliary plate through the opening, and
the connecting pillars are disposed lower than the auxiliary plate.

14. The lifting apparatus of claim 2, further comprising:
a plurality of first connecting parts extending in the second direction and spaced apart from each other in the first direction;
a plurality of second connecting parts extending in the second direction, spaced apart from each other in the first direction, disposed on the first connecting parts, and connected to the first connecting parts;
a plurality of side surface connecting parts connected to inner surfaces of the second connecting parts facing each other in the first direction; and
a plurality of chamber connecting parts connected to lower ends of the leg parts,
wherein the leg parts are disposed below the first connecting parts and connected to the first connecting parts,
wherein first side portions of the main plate adjacent to both the opposing sides of the main plate, which are opposite to each other in the first direction, and portions of the auxiliary plate overlapping the first side portions are disposed below the side surface connecting parts and connected to the side surface connecting parts, and
wherein second side portions of the auxiliary plate adjacent to both the opposing sides of the auxiliary plate, which are opposite to each other in the first direction, are disposed between the first and second connecting parts and connected to the first and second connecting parts.

15. The lifting apparatus of claim 14, wherein extending openings which extend in the second direction are defined in each of the first and second connecting parts.

16. The lifting apparatus of claim 2, further comprising:
a dummy auxiliary plate disposed below the main plate,
wherein the dummy auxiliary plate is connected to the main plate by the coupling units.

17. The lifting apparatus of claim 16, wherein the main plate is disposed at a center of an area between the auxiliary plate and the dummy auxiliary plate.

18. The lifting apparatus of claim 16, further comprising:
a plurality of first connecting parts extending in the second direction and spaced apart from each other in the first direction;
a plurality of second connecting parts extending in the second direction, spaced apart from each other in the first direction, disposed on the first connecting parts, and connected to the first connecting parts; and
a plurality of chamber connecting parts connected to lower ends of the leg part,
wherein the leg parts are disposed below the first connecting parts and connected to the first connecting parts,
wherein first side portions adjacent to both the opposing sides of the main plate, which are opposite to each other in the first direction, are disposed between the first and second connecting parts and connected to the first and second connecting parts, and
wherein second side portions adjacent to both the opposing sides of the auxiliary plate, which are opposite to each other in the first direction, are bent upward and connected to inner surfaces of the first connecting parts facing each other in the first direction.

19. The lifting apparatus of claim 18, further comprising:
a reinforcement plate disposed below the main plate,
wherein both opposing sides of the reinforcement plate, which are opposite to each other in the first direction, are spaced apart from both the opposing sides of the main plate, respectively, and
the reinforcement plate is in contact with the main plate and connected to the main plate.

20. A chemical vapor deposition apparatus comprising:
a main plate extending longer in a first direction than a second direction which intersects the first direction;
an auxiliary plate disposed on the main plate and connected to the main plate;
a plurality of leg parts adjacent to both opposing sides of each of the main plate and the auxiliary plate and extending downward;
a plurality of chamber connecting parts connected to lower ends of the leg parts;
a head part connected to the main plate and protruding upward;
a plurality of connecting pillars connected to the main plate and extending downward;
a support ring connected to lower ends of the connecting pillars;
an upper chamber connected to the support ring and the chamber connecting parts; and
a lower chamber disposed below the upper chamber,
wherein the upper chamber and the lower chamber are coupled to each other to define a process space in which a chemical vapor deposition process is performed, and a thickness of a central portion of the main plate is greater than a thickness of each of both opposing side portions of the main plate, which are opposite to each other in the first direction.
